(19) United States
(12) Patent Application Publication
(10) Pub. No.: US 2025/0105045 A1
(43) Pub. Date: Mar. 27, 2025

(54) ELECTROSTATIC CHUCK

(71) Applicant: TOTO LTD., Fukuoka (JP)

(72) Inventors: Tetsuro ITOYAMA, Fukuoka (JP); Jumpei UEFUJI, Fukuoka (JP); Tomoki UMETSU, Fukuoka (JP)

(73) Assignee: TOTO LTD., Fukuoka (JP)

(21) Appl. No.: 18/883,506

(22) Filed: Sep. 12, 2024

(30) Foreign Application Priority Data
Sep. 22, 2023 (JP) 2023-158945

(51) Int. Cl. H01L 21/683; H01J 37/32

(52) U.S. Cl. CPC H01L 21/6833; H01J 37/32724; H01J 2237/2007

(57) ABSTRACT

An electrostatic chuck (10) includes a dielectric substrate (100) and a heater unit (300) configured to heat the dielectric substrate (100). The heater unit (300) includes a power supply portion (390) configured to receive a supply of power from an external source, a heat generation portion (331) that is a conductor drawn in a linear shape and configured to receive the supply of power from the power supply portion (390) and generate heat, and a bypass layer (370) connecting the power supply portion (390) and the heat generation portion (331). The heat generation portion (331) includes a widened portion (332) that is a section in which a line width of the heat generation portion (331) is locally widened. The bypass layer (370) is connected to the heat generation portion (331) at a plurality of locations in the widened portion (332).

### CROSS-REFERENCE TO RELATED APPLICATION

This application is based upon and claims the benefit of priority from Japanese Patent Application No. 2023-158945 filed on Sep. 22, 2023, the entire contents of which are incorporated herein by reference.

### TECHNICAL FIELD

The present invention relates to an electrostatic chuck.

### BACKGROUND ART

A semiconductor manufacturing device, such as an etching device, includes an electrostatic chuck as a device for adsorbing and holding a substrate, such as a silicon wafer, to be processed. An electrostatic chuck includes a dielectric substrate provided with an adsorbing electrode. A voltage is applied to the adsorbing electrode to generate an electrostatic force, causing the substrate placed on the dielectric substrate to be adsorbed and held.

When the semiconductor manufacturing device processes a substrate, temperature adjustment is required to ensure that in-plane temperature distribution of the substrate is as uniform as possible. In recent years, to achieve highly accurate temperature adjustment, an electrostatic chuck including a heater has been developed and is in practical use. The heater may be provided inside the dielectric substrate, or may be provided between the dielectric substrate and a base plate in a unitized state as described in, for example, Patent Document 1 below.

### CITATION LIST

### Patent Literature

Patent Document 1: JP 2021-197485 A

### SUMMARY OF INVENTION

### Technical Problem

The heater includes a power supply portion, such as a power supply terminal, and a heat generation portion that is a linearly drawn conductor. When power is supplied from an external source to the power supply portion and a current flows through the heat generation portion, Joule heat is generated in the heat generation portion.

Preferably, the power supply portion and the heat generation portion are not directly connected to each other and are connected via a bypass portion interposed therebetween. The presence of the bypass portion makes it possible to improve the degree of freedom of arrangement of the power supply portion in the heater, and the like.

In this case, part of the bypass portion is connected to the heat generation portion by, for example, welding. A section of the heat generation portion to which the bypass portion is connected is hereinafter also referred to as a “connecting portion”. When the heater generates heat, a current flows through a relatively narrow connecting portion, which may cause a rise in local temperature at the connecting portion. As a result, the in-plane temperature distribution of the substrate during processing may become non-uniform, for example, which may adversely affect the processing.

The present invention has been made in view of such problems, and an object thereof is to provide an electrostatic chuck that can suppress a rise in local temperature in a heater.

### Solution to Problem

To solve the problem described above, an electrostatic chuck according to the present invention includes a dielectric substrate and a heater configured to heat the dielectric substrate. The heater includes a power supply portion configured to receive a supply of power from an external source, a heat generation portion that is a conductor drawn in a linear shape and configured to receive a supply of power from the power supply portion and generate heat, and a bypass portion connecting the power supply portion and the heat generation portion. The heat generation portion includes a widened portion that is a section in which a line width of the heat generation portion is locally widened. The bypass portion is connected to the heat generation portion at a plurality of locations in the widened portion.

In the electrostatic chuck having such a configuration, a current supplied to the heat generation portion flows through a path passing through a section of the widened portion where the bypass portion is connected. This section is hereinafter also referred to as a “connecting portion”.

The bypass portion is connected to the heat generation portion at a plurality of locations in the widened portion. That is, a plurality of the connecting portions described above are present in one widened portion. In such a configuration, the current supplied from the bypass portion to the heat generation portion does not flow in a concentrated manner in a single connecting portion, but flows in a distributed manner in a plurality of the connecting portions. The Joule heat generated per connecting portion is reduced, making it possible to suppress a rise in local temperature at the connecting portion.

### Advantageous Effects of Invention

According to the present invention, it is possible to provide an electrostatic chuck that can suppress a rise in local temperature in a heater.

### BRIEF DESCRIPTION OF DRAWINGS

FIG. 1 is a cross-sectional view schematically illustrating a configuration of an electrostatic chuck according to an embodiment.

FIG. 2 is an exploded view schematically illustrating a configuration of a heater unit.

FIG. 3 is a view illustrating an example of an arrangement of sub-heater layers in the heater unit.

FIG. 4 is a view illustrating a configuration of one sub-heater layer.

FIG. 5 is a view illustrating an example of an arrangement of main heater layers in the heater unit.

FIG. 6 is a view illustrating a configuration of one main heater layer.

FIG. 7 is a view for explaining a role and the like of a bypass layer.

FIG. 8 is a cross-sectional view illustrating a configuration of a welded portion and its vicinity in the heater unit.

FIG. 9 is a view illustrating an example of an arrangement of connecting portions in a widened portion.

FIG. 10 is a view illustrating an example of an arrangement of the connecting portions in the widened portion.

FIG. 11 is a view illustrating an example of an arrangement of the connecting portions in the widened portion.

FIG. 12 is a view illustrating an example of an arrangement of the connecting portions in the widened portion.

FIG. 13 is a view illustrating an example of an arrangement of the connecting portions in the widened portion.

### DESCRIPTION OF EMBODIMENTS

Hereinafter, embodiments will be described with reference to the accompanying drawings. To facilitate understanding of the description, similar components in the drawings are denoted by like reference signs to the extent possible, and duplicate description thereof will be omitted.

An electrostatic chuck 10 according to the present embodiment adsorbs and holds a substrate W to be processed by an electrostatic force inside a semiconductor manufacturing device (not illustrated), such as an etching device. The substrate W, which is an adsorbed object, is a silicon wafer, for example. The electrostatic chuck 10 may be used in a device other than a semiconductor manufacturing device.

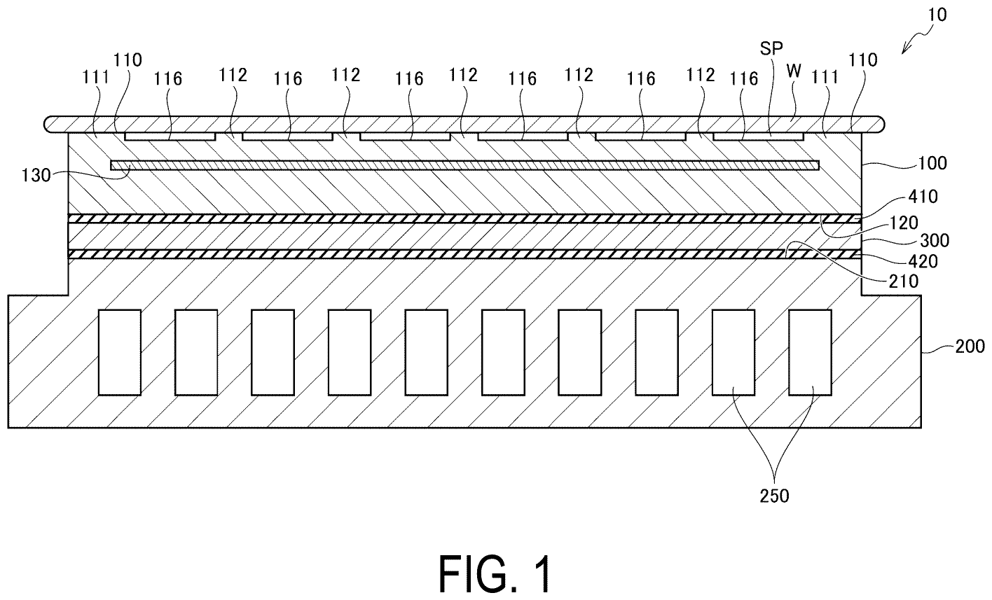

FIG. 1 illustrates, in a schematic cross-sectional view, a configuration of the electrostatic chuck 10 in a state of adsorbing and holding the substrate W. The electrostatic chuck 10 includes a dielectric substrate 100, a base plate 200, and a heater unit 300.

The dielectric substrate 100 is a substantially disk-shaped member made of a ceramic sintered body. The dielectric substrate 100 includes, for example, aluminum oxide (Al₂O₃) having high purity, but may include other materials. The purity, type, additives, and the like of the ceramic of the dielectric substrate 100 can be set as appropriate in consideration of plasma resistance and other characteristics required of the dielectric substrate 100 in the semiconductor manufacturing device.

A surface 110 of the dielectric substrate 100 on an upward side in FIG. 1 is a “placement surface” on which the substrate W is placed. Further, a surface 120 of the dielectric substrate 100 on a downward side in FIG. 1 is a “bonded surface” bonded to the heater unit 300 via a bonding layer 410. Hereinafter, a viewpoint when viewing the electrostatic chuck 10 from the surface 110 side in a direction perpendicular to the surface 110 is also referred to as a “top view”.

An adsorbing electrode 130 is embedded inside the dielectric substrate 100. The adsorbing electrode 130 is a layer having a thin flat plate shape, formed of a metal material such as tungsten, and is disposed parallel to the surface 110. As a material of the adsorbing electrode 130, molybdenum, platinum, palladium, or the like may be used in addition to or instead of tungsten. A voltage is applied to the adsorbing electrode 130 from an external source via a power supply path (not illustrated) to generate an electrostatic force between the surface 110 and the substrate W, causing the substrate W to be adsorbed and held. As the configuration of the power supply path, various known configurations can be adopted. For the adsorbing electrode 130, only one may be provided as a so-called “unipolar” electrode, as in the present embodiment, or two adsorbing electrodes may be provided as so-called “bipolar” electrodes.

As illustrated in FIG. 1, a space SP is formed between the dielectric substrate 100 and the substrate W. When processing such as etching is performed in the semiconductor manufacturing device, helium gas for temperature adjustment is supplied from an external source to the space SP via a gas hole (not illustrated). When the helium gas is present between the dielectric substrate 100 and the substrate W, the thermal resistance between the dielectric substrate 100 and the substrate W is adjusted such that the temperature of the substrate W is maintained at an appropriate temperature. Note that the gas used for temperature adjustment that is supplied to the space SP may be a gas of a type different from helium.

On the surface 110 that is the placement surface, a sealing ring 111 and dots 112 are provided, and the space SP is formed around them.

The sealing ring 111 is a wall defining the space SP at a position corresponding to an outermost perimeter. An upper end of the sealing ring 111 is part of the surface 110 and abuts against the substrate W. Note that a plurality of the sealing rings 111 may be provided, dividing the space SP. With such a configuration, it is possible to individually adjust the pressure of the helium gas in each space SP and make a surface temperature distribution of the substrate W during processing close to uniform.

A section denoted by reference sign “116” in FIG. 1 is a bottom surface of the space SP. Hereinafter, this section is also referred to as “bottom surface 116”. The sealing ring 111 is formed as a result of recessing part of the surface 110, along with the dots 112 described next, to the position of the bottom surface 116.

The dot 112 is a circular projection protruding from the bottom surface 116. A plurality of the dots 112 are provided and arranged dispersed in a substantially uniform manner on the placement surface of the dielectric substrate 100. An upper end of each dot 112 forms part of the surface 110 and abuts against the substrate W. With the plurality of dots 112 being provided, deflection of the substrate W is suppressed.

The base plate 200 is a substantially disc-shaped member that supports the dielectric substrate 100 and the heater unit 300. The base plate 200 is formed of a metal material such as aluminum. A surface 210 of the base plate 200 on the upward side in FIG. 1 is a “bonded surface” bonded to the heater unit 300 via a bonding layer 420.

A coolant flow channel 250 through which a coolant flows is formed inside the base plate 200. When processing such as etching is performed in the semiconductor manufacturing device, the coolant is supplied from an external source to the coolant flow channel 250, thereby cooling the base plate 200. Heat generated in the substrate W during processing is transferred to the coolant via the helium gas in the space SP, the dielectric substrate 100, and the base plate 200, and is exhausted to the outside together with the coolant.

An insulating film may be formed on a surface of the base plate 200. As the insulating film, for example, an alumina film formed by thermal spraying can be used. By covering the surface of the base plate 200 with an insulating film, it is possible to increase a withstand voltage of the base plate 200.

The heater unit 300 receives a supply of power from an external source and generates heat, thereby heating the dielectric substrate 100. As described below, the heater unit 300 includes a plurality of heat generation portions 331 or the like, and a heat generation amount of each of the heat generation portions 331 or the like can be individually adjusted. By individually adjusting the heat generation amount of each portion, it is possible to make the in-plane temperature distribution of the substrate W during processing close to uniform.

The heater unit 300 is interposed between the dielectric substrate 100 and the base plate 200, and is bonded to each of them. The heater unit 300 and the dielectric substrate 100 are bonded to each other via the bonding layer 410, and the heater unit 300 and the base plate 200 are bonded to each other via the bonding layer 420. The bonding layers 410, 420 are layers formed by curing a silicone adhesive, for example. A plurality of particulate fillers for increasing thermal conductivity are disposed inside each bonding layer 410 and 420. As the filler, for example, particles containing alumina as a main component can be used.

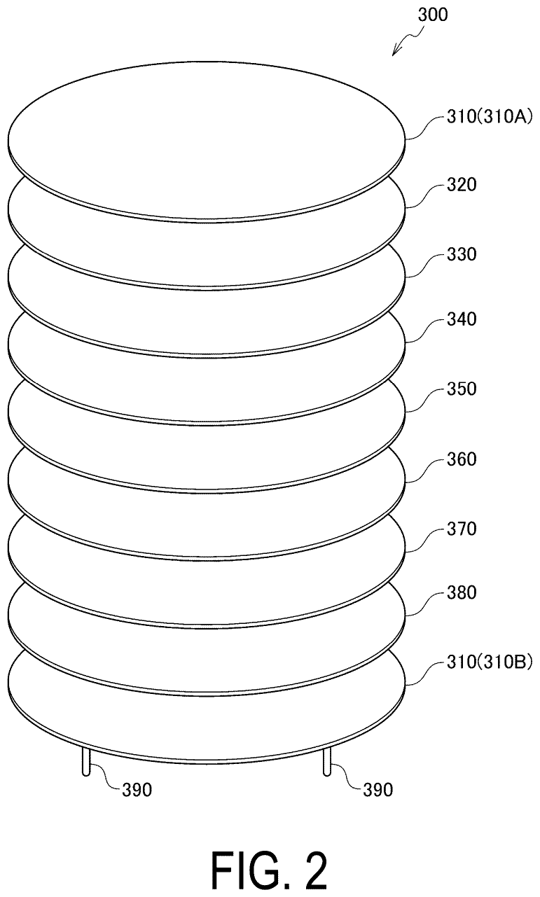

A specific configuration of the heater unit 300 will now be described. FIG. 2 is a schematic exploded assembly view illustrating a configuration of the heater unit 300. As illustrated in the drawing, the heater unit 300 includes a support plate 310 (310A), an insulating layer 320, a sub-heater layer 330, an insulating layer 340, a main heater layer 350, an insulating layer 360, a bypass layer 370, an insulating layer 380, a support plate 310 (310B), and power supply portions 390. Note that, in the present embodiment, the sub-heater layer 330, the main heater layer 350, and the bypass layer 370 are disposed in this order from the top, but the order of arrangement may be an order different from that of the present embodiment.

The support plate 310 is a substantially disk-shaped member, and is provided at both upper and lower end portions of the heater unit 300 in FIG. 2. The support plate 310 provided at the upper end portion in FIG. 2 is hereinafter also referred to as “support plate 310A”. The support plate 310 provided at the lower end portion in FIG. 2 is hereinafter also referred to as “support plate 310B”. The support plate 310A is a section bonded to the dielectric substrate 100 via the bonding layer 410, and the support plate 310B is a section bonded to the base plate 200 via the bonding layer 420.

The pair of support plates 310A, 310B are members for reinforcing the entire heater unit 300 by sandwiching all of the sub-heater layer 330, the main heater layer 350, the bypass layer 370, and the like. In the present embodiment, the support plates 310A, 310B are both formed of metal, but may be formed of other members (e.g., insulating members). As described below, openings 311 are formed in the support plates 310A, 310B, but are not illustrated in FIG. 2.

The insulating layer 320 is provided between the support plate 310A and the sub-heater layer 330, and is a layer for electrically insulating the support plate 310A and the sub-heater layer 330 from each other. Further, the insulating layer 320 also has a role of physically bonding the support plate 310A and the sub-heater layer 330. The insulating layer 320 is a polyimide film in the present embodiment, but may contain a component other than polyimide and may be formed of a material different from polyimide. In a case where the support plate 310A is formed of an insulating material, the insulating layer 320 may be omitted.

The sub-heater layer 330 is a section that generates heat by receiving a supply of power from an external source. Although the sub-heater layer 330 is schematically illustrated as a single circular plate in FIG. 2, the sub-heater layer 330 is actually divided into a plurality of regions, and each region can be individually caused to generate heat. A specific configuration of the sub-heater layer 330 is described below.

The insulating layer 340 is provided between the sub-heater layer 330 and the main heater layer 350, and is a layer for electrically insulating the sub-heater layer 330 and the main heater layer 350 from each other. Further, the insulating layer 340 also has a role of physically bonding the sub-heater layer 330 and the main heater layer 350. The insulating layer 340 is a polyimide film in the present embodiment, but may contain a component other than polyimide and may be formed of a material different from polyimide.

Similar to the sub-heater layer 330 described above, the main heater layer 350 is a section that generates heat by receiving a supply of power from an external source. Although the main heater layer 350 is schematically illustrated as a single circular plate in FIG. 2, the main heater layer 350 is actually divided into a plurality of regions, and each region can be individually caused to generate heat. A specific configuration of the main heater layer 350 is described below.

The main heater layer 350 generates a larger amount of heat as compared with the sub-heater layer 330 described above. The main heater layer 350 is a layer for raising a temperature of the dielectric substrate 100 as a whole in a short period of time. The sub-heater layer 330 is a layer for adjusting a temperature of each component of the dielectric substrate 100 and making the in-plane temperature distribution of the substrate W close to uniform. Thus, in the present embodiment, two heater layers corresponding to individual roles are individually provided. Instead of such a form, a configuration including only one heater layer may be adopted.

The insulating layer 360 is provided between the main heater layer 350 and the bypass layer 370, and is a layer for electrically insulating the main heater layer 350 and the bypass layer 370 from each other. Further, the insulating layer 360 also has a role of physically bonding the main heater layer 350 and the bypass layer 370. The insulating layer 360 is a polyimide film in the present embodiment, but may contain a component other than polyimide and may be formed of a material different from polyimide.

The bypass layer 370 is a layer for electrically connecting the power supply portions 390 described below to the sub-heater layer 330 and the main heater layer 350. Although the bypass layer 370 is schematically illustrated as a single circular plate in FIG. 2, the bypass layer 370 is actually divided into a plurality of components. By providing the bypass layer 370 in the middle of the electric path connected to the sub-heater layer 330 and the like, it is possible to adjust positions of the power supply portions 390. Each of the bypass layers 370 is partially welded to the sub-heater layer 330 or the main heater layer 350. Each of the bypass layers 370 corresponds to a “bypass portion” in the present embodiment.

The insulating layer 380 is provided between the bypass layer 370 and the support plate 310B, and is a layer for electrically insulating the bypass layer 370 and the support plate 310B from each other. Further, the insulating layer 380 also has a role of physically bonding the bypass layer 370 and the support plate 310B. The insulating layer 380 is a polyimide film in the present embodiment, but may contain a component other than polyimide and may be formed of a material different from polyimide. In a case where the support plate 310B is formed of an insulating material, the insulating layer 380 may be omitted.

During manufacture of the heater unit 300, the layers illustrated in FIG. 2 are pressed and heated entirely in a layered state. As a result, all the layers are bonded and integrated via the insulating layer 320, which is a polyimide film, and the like.

The power supply portion 390 is a section that receives, from an external source, power necessary for causing the sub-heater layer 330 and the like to generate heat. In the present embodiment, the power supply portion 390 is formed as an elongated rod-shaped plug, and one end portion of the power supply portion 390 is connected to the bypass layer 370. A plurality of the power supply portions 390 are provided in a number corresponding to the number of bypass layers 370, but only two are illustrated in FIG. 2. Through-holes (not illustrated) are formed in the base plate 200 at positions corresponding to the power supply portions 390, and the power supply portions 390 are inserted into the through-holes.

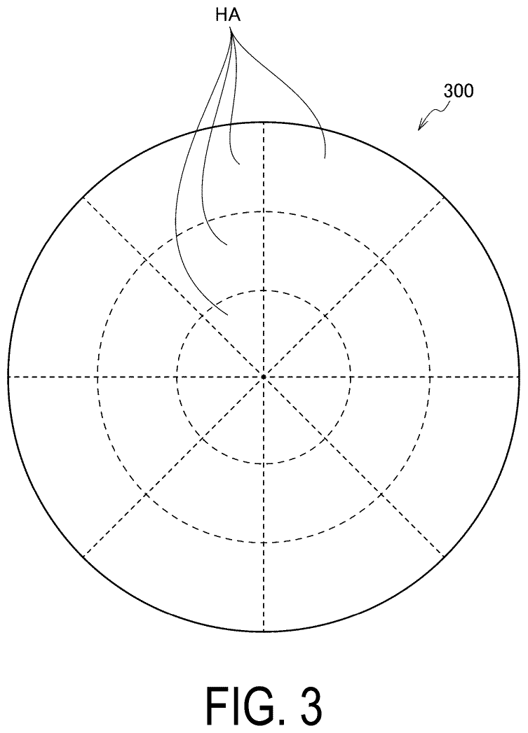

A configuration of the sub-heater layer 330 will now be described. As described above, the sub-heater layer 330 is divided into a plurality of regions, and heat can be individually generated in each region. FIG. 3 is a top view of an example of how to divide the sub-heater layer 330. In this example, the sub-heater layer 330 is divided into a total of 24 regions HA.

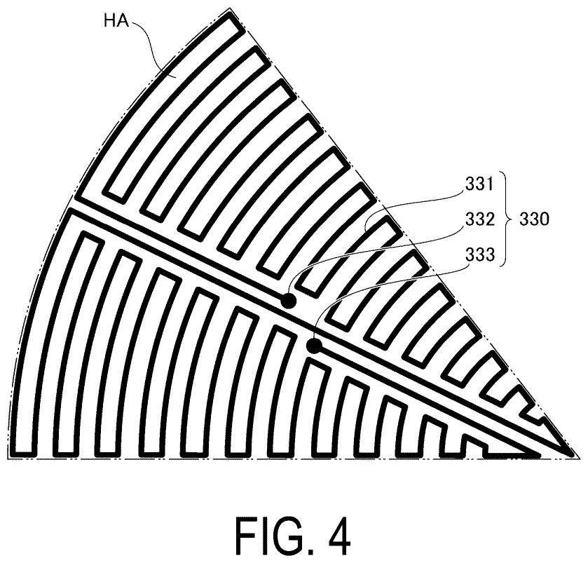

Each of the sub-heater layers 330 is configured as the heat generation portion 331 having a linear shape, and is individually drawn in each region HA. The heat generation portion 331 is a conductor drawn in a linear shape, and generates heat by receiving a supply of power from the power supply portion 390. FIG. 4 illustrates an example of the heat generation portion 331 drawn in one region HA. In each of the regions HA, one heat generation portion 331 having a linear shape is drawn along a path that passes through the entire region HA substantially equally. Two or more heat generation portions 331 connected in parallel to each other may be drawn.

Widened portions 332, 333 each having a circular shape are formed at both ends of the heat generation portion 331. Each of the widened portions 332, 333 is part of the heat generation portion 331, and is a section with a locally widened line width. The widened portions 332, 333 are sections to which the bypass layer 370 is electrically connected via a welded portion 301 described below. The shape of each widened portion 332, 333 may be circular as in the present embodiment, but may be a shape other than circular.

The heat generation portion 331 including the widened portions 332, 333 is formed by, for example, etching a thin metal foil, and the entire heat generation portion 331 functions as one sub-heater layer 330. In other words, one sub-heater layer 330 is provided for each of the total of 24 regions HA.

Note that the shape of the sub-heater layer 330 illustrated in FIG. 4 is schematic and may differ from the actual shape. For example, there may be a sub-heater layer 330 in which the widened portion 332 or the like is not provided at the end portion of the heat generation portion 331, but is provided at a position partway along the heat generation portion 331.

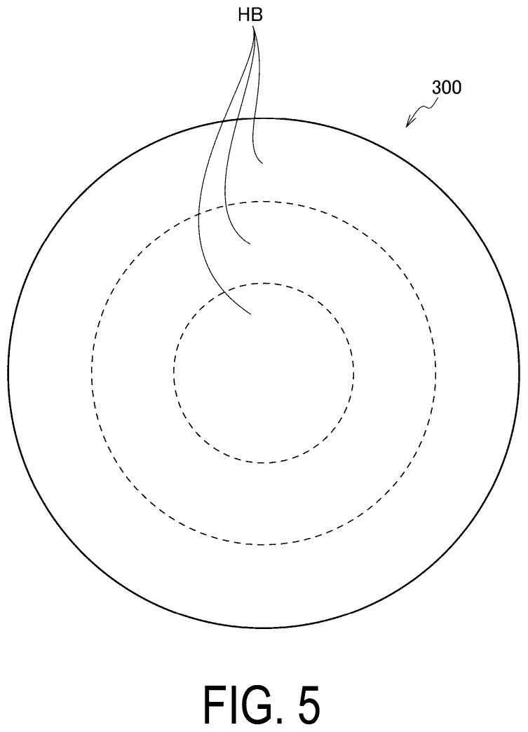

A configuration of the main heater layer 350 will now be described. Similar to the sub-heater layer 330, the main heater layer 350 is also divided into a plurality of regions, and heat can be individually generated in each region. FIG. 5 is a top view of an example of how to divide the main heater layer 350. In this example, the main heater layer 350 is divided into a total of three regions HB.

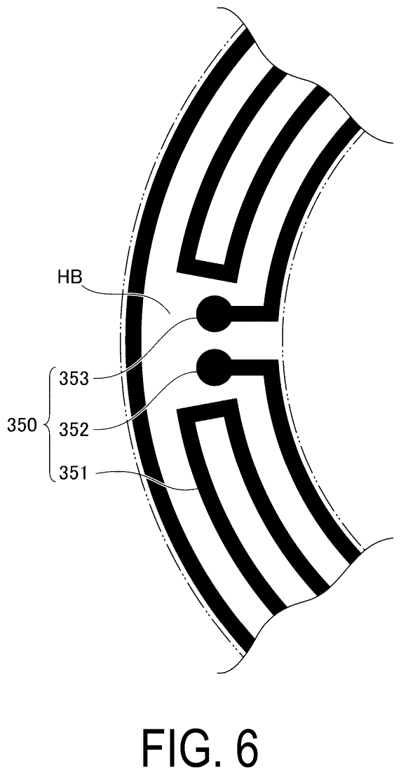

Each of the main heater layers 350 is configured as a heat generation portion 351 having a linear shape, and is individually drawn in each region HB. Similar to the heat generation portion 331, the heat generation portion 351 is a conductor drawn in a linear shape, and generates heat by receiving a supply of power from the power supply portion 390. FIG. 6 illustrates an example of the heat generation portion 351 drawn in one region HB. In each of the regions HB, one heat generation portion 351 having a linear shape is drawn along a path that passes through the entire region HB substantially equally. Two or more heat generation portions 351 connected in parallel to each other may be drawn.

Widened portions 352, 353 each having a circular shape are formed at both ends of the heat generation portion 351. Each of the widened portions 352, 353 is part of the heat generation portion 351, and is a section having a locally widened line width. The widened portions 352, 353 are sections to which the bypass layer 370 is electrically connected via the welded portion 301. The shape of each widened portion 352, 353 may be circular as in the present embodiment, but may be a shape other than circular.

The heat generation portion 351 including the widened portions 352, 353 is formed by, for example, etching a thin metal foil, and the entire heat generation portion 351 functions as one main heater layer 350. In other words, one main heater layer 350 is provided for each of the total of three regions HB.

Note that the shape of the main heater layer 350 illustrated in FIG. 6 is schematic and may differ from the actual shape. For example, there may be a main heater layer 350 in which the widened portion 352 or the like is not provided at the end portion of the heat generation portion 351, but provided at a position partway along the heat generation portion 351.

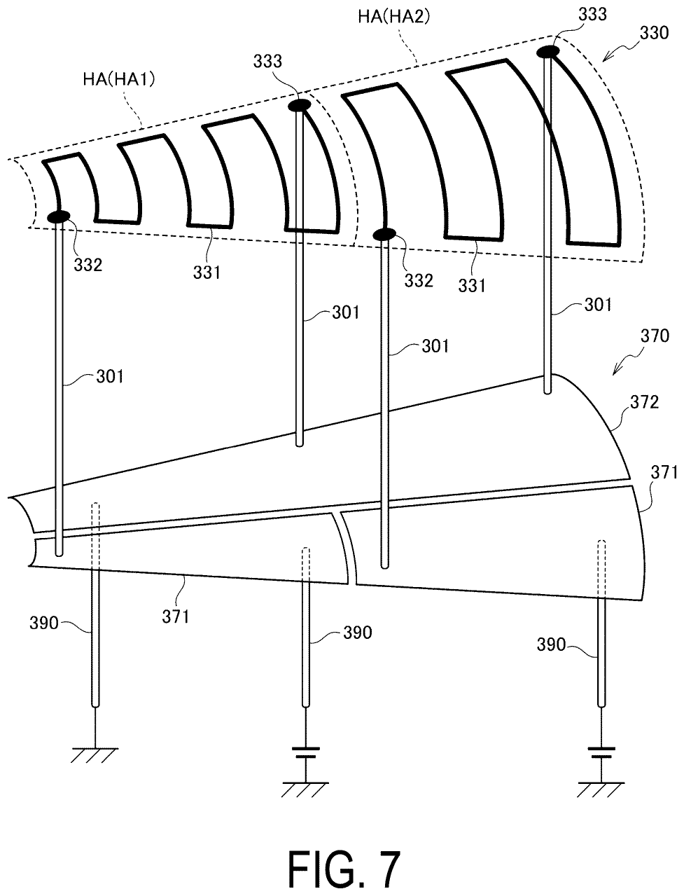

FIG. 7 is a schematic perspective view of a configuration of two regions HA, two sub-heater layers 330 disposed in the two regions HA, the bypass layer 370 connected to the sub-heater layers 330, and the like. One of the two regions HA illustrated in FIG. 7 is hereinafter also referred to as “region HA1”. The other region HA is hereinafter also referred to as “region HA2”. Note that the shapes of the heat generation portion 331 and the like illustrated in FIG. 7 are schematic and may differ from the actual shapes.

As described above, the bypass layer 370 is divided into a plurality of components. In FIG. 7, only three of the plurality of bypass layers 370 are illustrated. Among the three bypass layers 370, each of the bypass layers denoted by reference sign “371” in FIG. 7 is disposed at a position overlapping only the corresponding one of the regions HA in a top view. That is, the bypass layers denoted by reference sign “371” are individually disposed at positions immediately below the respective regions HA. The section of the bypass layer 370 arranged in this manner is hereinafter also referred to as “bypass layer 371”.

Among the bypass layers 370, the bypass layer denoted by reference sign “372” in FIG. 7 is disposed at a position overlapping both the region HAI and the region HA2 in a top view. The section of the bypass layer 370 arranged in this manner is hereinafter also referred to as “bypass layer 372”.

In the sub-heater layer 330 disposed in the region HA1, the widened portion 332 at one end of the heat generation portion 331 is electrically connected to the bypass layer 371 immediately below. The widened portion 333 at the other end of the heat generation portion 331 is electrically connected to the bypass layer 372.

The same applies to the sub-heater layer 330 disposed in the region HA2, and the widened portion 332 at one end of the heat generation portion 331 is electrically connected to the bypass layer 371 immediately below. The widened portion 333 at the other end of the heat generation portion 331 is electrically connected to the bypass layer 372.

Note that, in the present embodiment, electrical connections between each component such as described above are achieved by welding the upper and lower layers to each other. To facilitate understanding of the configuration, in FIG. 7, each welded portion is schematically depicted as a linearly extending rod-like member (section denoted by reference sign 301), but the actual shape of the welded portion may be different. Note that, in a section overlapping each welded portion in a top view, an opening is formed in each of the layers (insulating layer 340, main heater layer 350, and insulating layer 360) between the sub-heater layer 330 and the bypass layer 370, and the sub-heater layer 330 and the bypass layer 370 directly overlap each other through the opening.

One end of each power supply portion 390 is connected to the corresponding bypass layer 371 from a lower side in FIG. 7. A voltage is individually applied to each of these power supply portions 390 from an external direct current power supply. Similarly, one end of the power supply portion 390 is connected to the bypass layer 372 from the lower side in FIG. 7. This power supply portion 390 is grounded.

As described above, in each of the sub-heater layers 330 (heat generation portions 331) provided for each region HA, the widened portion 332 is connected to an individual direct current power supply via the bypass layer 371, and the widened portion 333 is grounded via the common bypass layer 372. The other sub-heater layers 330 not illustrated in FIG. 7 are also connected to a direct current power supply or the like by a similar configuration. With such a configuration, it is possible to individually supply power to each of the plurality of sub-heater layers 330 and adjust the heat generation amount in each component.

It is also possible to supply power to the sub-heater layer 330 directly from the power supply portion 390 and not through the bypass layer 370. However, by adopting a configuration in which power is supplied via the bypass layer 370 as in the present embodiment, it is possible to increase a degree of freedom in the arrangement of the power supply portions 390, integrate the grounded power supply portions 390 into one, and the like.

The supply of electric power to each main heater layer 350 is also provided by the same configuration as described above. The specific configuration is the same as that illustrated in FIG. 7, and thus description and illustration thereof will be omitted. The bypass layer 370 connected to the sub-heater layer 330 and the bypass layer 370 connected to the main heater layer 350 may be disposed at the same height position (position of the bypass layer 370 illustrated in FIG. 2) as in the present embodiment, but may be disposed at height positions different from each other.

As described above, in the heater unit 300, the sub-heater layer 330 and the bypass layer 370 are welded and electrically connected to each other. Such a welded section is hereinafter also referred to as “welded portion 301”.

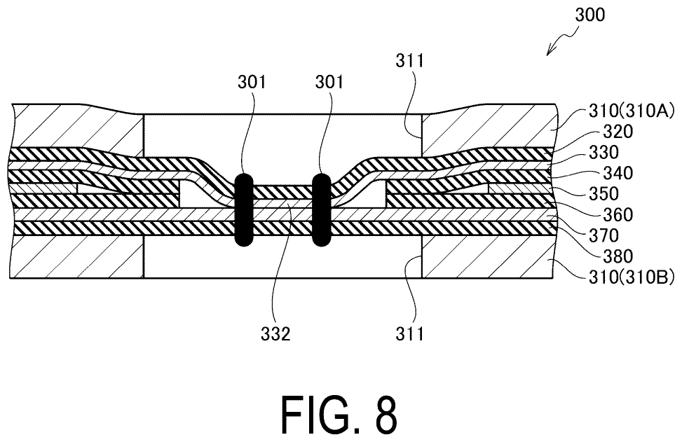

FIG. 8 is a cross-sectional view illustrating a configuration of the welded portion 301 and its vicinity in the heater unit 300. As illustrated in FIG. 8, in part of the heater unit 300, the sub-heater layer 330 and the bypass layer 370 overlap each other without the insulating layers 340, 360 and the main heater layer 350 interposed therebetween, and are integrally connected to each other by resistance spot welding, for example. Sections of the heat generation portion 331 positioned on an inner side of the widened portions 332, 333 are connected to the bypass layer 370 by the welded portions 301.

In the present embodiment, as illustrated in FIG. 8, two welded portions 301 are formed at positions close to each other. That is, the two welded portions 301 illustrated in FIG. 7 are actually formed at each of the widened portions 332 (or widened portions 333). Note that three or more welded portions 301 may be arranged close to each other on an inner side of one widened portion 332. The quantity of and interval between the welded portions 301 may be set as appropriate depending on a welding method to be adopted or the like.

After the sub-heater layer 330 and the bypass layer 370 are welded to each other as described above, the sub-heater layer 330 and the like are sandwiched between the pair of support plates 310. The welded portion 301 is raised as described above, and protrudes upwardly from the insulating layer 320 and downwardly from the insulating layer 380 in FIG. 8. Accordingly, depending on a size of the welded portion 301, when the sub-heater layer 330 and the like are entirely sandwiched between the pair of support plates 310, the welded portion 301 may come into contact with the support plates 310, and an outer surface of the support plate 310 may be locally convexly deformed.

Therefore, in the electrostatic chuck 10 according to the present embodiment, an opening 311 is formed at a position of the support plate 310 facing the welded portion 301. The opening 311 is a circular opening and, in a top view, two welded portions 301 are accommodated in an inner part of one opening 311. Since the welded portion 301 does not come into contact with the support plate 310, even if the welded portion 301 is locally raised, the support plate 310 does not deform due to the raised portion.

The opening 311 may be formed in both of the pair of support plates 310A, 310B, but may be formed in only one of them. However, if the opening 311 is formed in both support plates 310A, 310B as in the present embodiment, deformation of the support plates 310 can be prevented on both sides of the heater unit 300, and thus formation in both is preferable.

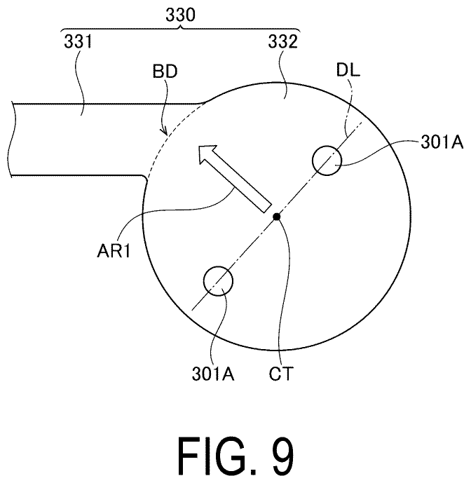

FIG. 9 is a top view of a configuration of the vicinity of the widened portion 332 at the end portion of the heat generation portion 331. As described above, the widened portion 332 is connected to the bypass layer 370 via each of the two welded portions 301. A section of the widened portion 332 where the welded portion 301 is provided, that is, a section of the widened portion 332 to which the bypass layer 370 is connected is hereinafter also referred to as “connecting portion 301A”.

In the present embodiment, two or more connecting portions 301A are provided in each of all the widened portions 332 or the like included in the heat generation portion 331. In other words, the bypass layer 370 is connected to the heat generation portion 331 at a plurality of locations in an inner part of each of the widened portions 332 or the like.

In a case in which only one connecting portion 301A is provided in an inner part of the widened portion 332, since a current passes through the only one connecting portion 301A, which is relatively narrow, when the heater unit 300 generates heat, a rise in local temperature may occur at the connecting portion 301A. As a result, the in-plane temperature distribution of the substrate W during the processing may become non-uniform or the like, which may adversely affect the processing.

Therefore, in the present embodiment, as described above, the bypass layer 370 is connected to the heat generation portion 331 at a plurality of locations in the widened portion 332. In such a configuration, the current supplied from the bypass layer 370 to the widened portion 332 of the heat generation portion 331 does not flow in a concentrated manner through a single connecting portion 301A, but flows in a distributed manner in the plurality of connecting portions 301A. Since the Joule heat generated per connecting portion 301A is reduced, it is possible to suppress a rise in local temperature at the connecting portion 301A.

In FIG. 9, a dotted line denoted by reference sign “BD” indicates a boundary section between the widened portion 332 and the other sections of the heat generation portion 331. Such a boundary section is hereinafter also referred to as “boundary portion BD”. Further, a dotted line DL illustrated in FIG. 9 is a line passing through a center of each of the two connecting portions 301A inside the widened portion 332. The dotted line DL indicates a direction in which the two connecting portions 301A are aligned.

An arrow AR1 illustrated in FIG. 9 indicates a direction from a center CT of the widened portion 332 toward the boundary portion BD. Specifically, the “direction toward the boundary portion BD” is a direction toward a center of the boundary portion BD in a width direction. Note that, when the shape of the widened portion 332 in a top view is a shape other than a circle, the “center CT of the widened portion 332” is a center of gravity of the widened portion 332.

In the present embodiment, the dotted line DL extends in a direction perpendicular to the direction indicated by the arrow AR1 in FIG. 9. That is, the pair of connecting portions 301A in the widened portion 332 are disposed in alignment in a direction perpendicular to the direction from the center CT of the widened portion 332 toward the boundary portion BD (that is, direction of the dotted line DL).

In such a configuration, a magnitude of the current flowing from each of the connecting portions 301A to the boundary portion BD can be made substantially equal. Since a current flows to one connecting portion 301A while not being biased, it is possible to further suppress a rise in local temperature at the connecting portion 301A.

Thus, in the present embodiment, in addition to provision of the plurality of connecting portions 301A in one widened portion 332, the specific arrangement of these connecting portions 301A enables the occurrence of a rise in local temperature to be sufficiently suppressed.

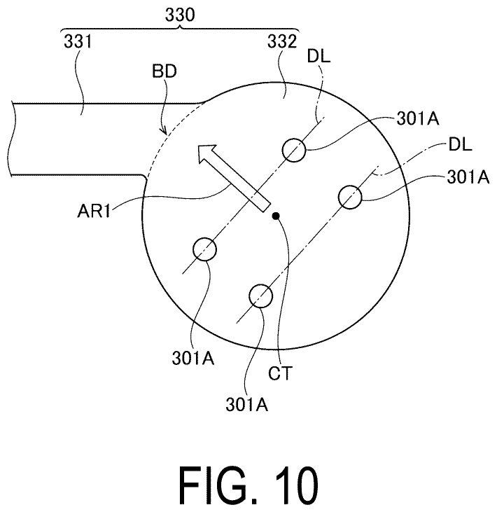

Note that the number of the connecting portions 301A provided in one widened portion 332 may be three or more. In the example illustrated in FIG. 10, four connecting portions 301A are provided in one widened portion 332. More specifically, two sets of the pair of connecting portions 301A aligned in the direction (dotted line DL) perpendicular to the arrow AR1 are provided in one widened portion 332. As in the examples of FIGS. 9 and 10, the plurality of connecting portions 301A in the widened portion 332 may include at least one or more sets of the pair of connecting portions 301A disposed in alignment in the direction perpendicular to the direction from the center CT of the widened portion 332 toward the boundary portion BD.

In the example of FIG. 10, distances between each pair of connecting portions 301A aligned along the dotted line DL are equal to each other in each set. As a result, the four connecting portions 301A are disposed at positions corresponding to vertices of a rectangle. With such a configuration, bonding strength between the widened portion 332 and the bypass layer 370 can be sufficiently maintained while maintaining a balance between the currents in each connecting portion 301A. The shape that is formed by connecting the respective centers of the four connecting portions 301A may be a rectangle as in the present embodiment, but may be a square.

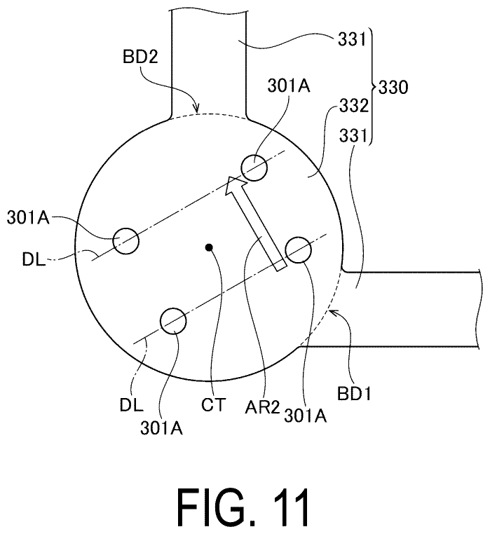

As described above, the widened portion 332 and the like may be formed at the end portion of the linearly extending heat generation portion 331, but may be formed at a position partway along the heat generation portion 331. FIG. 11 illustrates an example of an arrangement of the connecting portions 301A in the widened portion 332 formed at positions partway along the heat generation portion 331. In this example, two boundary portions BD are adjacent to one widened portion 332. One boundary portion BD is hereinafter also referred to as “first boundary portion BD1”. The other boundary portion BD is hereinafter also referred to as “second boundary portion BD2”.

An arrow AR2 illustrated in FIG. 11 indicates a direction from the first boundary portion BD1 toward the second boundary portion BD2. “A direction from the first boundary portion BD1 toward the second boundary portion BD2” specifically refers to a direction from a center of the first boundary portion BD1 in its width direction toward a center of the second boundary portion BD2 in its width direction.

In the example of FIG. 11, each connecting portion 301A is disposed such that the dotted lines DL extend in a direction perpendicular to the direction indicated by the arrow AR2. That is, the plurality of connecting portions 301A in the widened portion 332 of FIG. 11 include the pair of connecting portions 301A disposed in a direction perpendicular to the direction from the first boundary portion BD1 toward the second boundary portion BD2 (that is, direction of the dotted line DL). In the example of FIG. 11, there are two sets of such a pair of connecting portions 301A, and four connecting portions 301A are disposed at positions corresponding to respective vertices of a rectangle, as in the example of FIG. 10. There may be only one set of the pair of connecting portions 301A aligned in the direction of the dotted line DL.

The direction of the arrow AR2 can be said to be the direction in which the current flowing along the linear heat generation portion 331 flows when passing through the widened portion 332. In the example of FIG. 11, the pairs of connecting portions 301A are arranged in a direction perpendicular to such a direction (that is, direction of the dotted line DL), making the currents flowing from the connecting portions 301A into the heat generation portion 331 substantially equal to each other.

Note that, also in the widened portion 332 having two boundary portions BD present as illustrated in FIG. 11, the connecting portions 301A may be arranged using a method similar to that of the example of FIG. 9. In this case, the pairs of connecting portions 301A in the widened portion 332 need only be disposed in alignment in a direction perpendicular to the direction from the center CT of the widened portion 332 toward any one of the boundary portions BD (that is, direction of the dotted line DL).

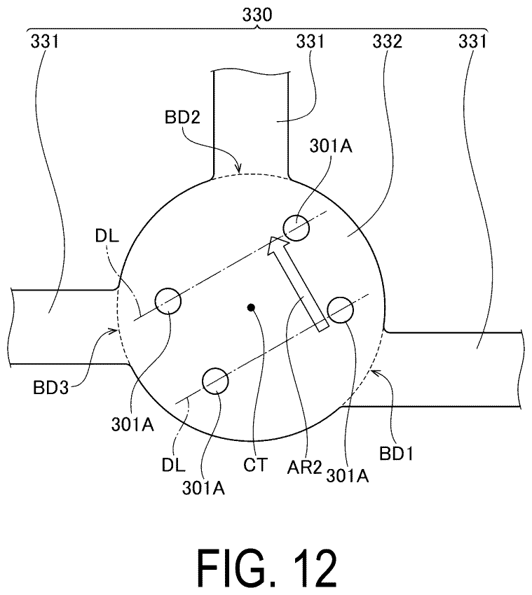

Even in a case in which three or more boundary portions BD are adjacent to one widened portion 332, the connecting portions 301A may be arranged using a method similar to any one of those of the examples described above. For example, in the example illustrated in FIG. 12, a configuration is adopted in which another boundary portion BD (third boundary portion BD3) is further added to the example of FIG. 11, but the rest of the configuration is the same as that of the example of FIG. 11. Thus, in a case in which three boundary portions BD are adjacent to one widened portion 332, the pairs of connecting portions 301A may be disposed by a method similar to that of the example of FIG. 10, regardless of the third boundary portion BD3. The connecting portions 301A may be arranged using a method similar to that of the example of FIG. 9.

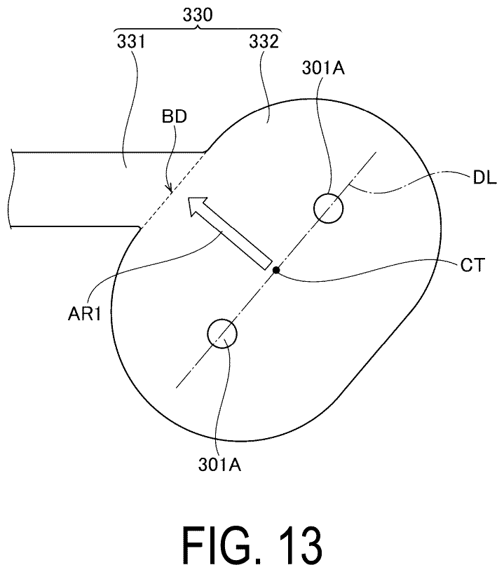

The shape of the widened portion 332 in a top view may be a shape other than a circle. In the example of FIG. 13, the shape of the widened portion 332 is elongated along the dotted line DL, and this is the only difference from the example of FIG. 9. Given a “first connecting portion” as one and a “second connecting portion” as the other of the pair of connecting portions 301A disposed along the dotted line DL, the widened portion 332 in FIG. 13 is formed extending from the first connecting portion toward the second connecting portion.

In such a configuration, the shape of the widened portion 332 can be made into a shape obtained by suppressing an area thereof to a minimum while encompassing each connecting portion 301A. The widened portion 332 is a section of the heat generation portion 331 that generates a relatively small amount of heat. With the size of such a widened portion 332 being suppressed to a minimum, a heating efficiency of the heater unit 300 can be sufficiently provided.

The number of connecting portions 301A provided in the widened portion 332 having a shape such as that illustrated in FIG. 13 may be three or more. For example, as in the example illustrated in FIG. 10, four connecting portions 301A may be provided, and these may be arranged at positions corresponding to respective vertices of a rectangle. In this case, each connecting portion 301A may be arranged such that a shape formed by connecting the centers of the four connecting portions 301A is a rectangle, and the shape of the widened portion 332 may be a shape extending in the direction of a long side of the rectangle.

The arrangement of the connecting portions 301A in the widened portion 332 has been described above. However, a similar configuration can be adopted for the arrangement of the connecting portions 301A in the widened portion 333 as well. Further, a configuration similar to that described above can be adopted for the configuration of the connecting section between the main heater layer 350 and the bypass layer 370 as well.

In the above, a configuration is described in which the heater for heating the dielectric substrate 100 is provided outside the dielectric substrate 100 in a state of being unitized as the heater unit 300. However, a configuration such as that described above can also be applied to a configuration in which the heater is provided inside the dielectric substrate 100.

That is, a form may be adopted in which the heat generation portion 331 made of a linearly drawn conductor is embedded inside the dielectric substrate 100 as a heater. In this case, the power supply portion 390 is provided on the surface 120 side of the dielectric substrate 100, and the bypass layer 370 connecting the power supply portion 390 and the heat generation portion 331 is embedded inside the dielectric substrate 100, similar to the heat generation portion 331. The connection between the bypass layer 370 and the heat generation portion 331 may be made through an elongated via (hole) filled with a conductor rather than through the welded portion 301 as in the present embodiment. In addition, the arrangement of sections of the widened portion 332 or the like to which the vias described above are connected (that is, sections corresponding to the connecting portions 301A) may be similar to that in any of the examples described above.

Embodiments have been described above with reference to specific examples. However, the present disclosure is not limited to these specific examples. Those skilled in the art can suitably modify these specific examples, and such modifications are also encompassed within the scope of the present disclosure as long as they include the features of the present disclosure. Each element included in each of the specific examples described above and the arrangement, condition, shape, and the like thereof are not limited to those described, and can be changed as appropriate. The combinations of the elements in each of the specific examples described above can be changed as appropriate, as long as no technical contradiction occurs.

1. An electrostatic chuck comprising:
a dielectric substrate; and
a heater configured to heat the dielectric substrate, wherein
the heater includes
a power supply portion configured to receive a supply of power from an external source;
a heat generation portion that is a conductor drawn in a linear shape, the heat generation portion being configured to receive a supply of power from the power supply portion and generate heat; and
a bypass portion connecting the power supply portion and the heat generation portion,
the heat generation portion includes a widened portion that is a section in which a line width of the heat generation portion is locally widened, and
the bypass portion is connected to the heat generation portion at a plurality of locations in the widened portion.

2. The electrostatic chuck according to claim 1, wherein
when a boundary section between the widened portion and other sections of the heat generation portion is defined as a boundary portion, and a section of the widened portion to which the bypass portion is connected is defined as a connecting portion,
a plurality of the connecting portions in the widened portion include a pair of the connecting portions disposed in alignment in a direction perpendicular to a direction from a center of the widened portion toward the boundary portion.

3. The electrostatic chuck according to claim 1, wherein
when a boundary section between the widened portion and other sections of the heat generation portion is defined as a boundary portion, and a section of the widened portion to which the bypass portion is connected is defined as a connecting portion,
a plurality of the boundary portions including a first boundary portion and a second boundary portion are adjacent to one of a plurality of the widened portions, and
a plurality of the connecting portions in the one widened portion include a pair of the connecting portions disposed in alignment in a direction perpendicular to a direction from the first boundary portion toward the second boundary portion.

4. The electrostatic chuck according to claim 1, wherein
when a section of the widened portion to which the bypass portion is connected is defined as a connecting portion,
a plurality of the connecting portions in the widened portion include a first connecting portion and a second connecting portion, and
the widened portion is formed extending from the first connecting portion toward the second connecting portion.

5. The electrostatic chuck according to claim 2, wherein
in the widened portion, four of the connecting portions are disposed at positions corresponding to respective vertices of a rectangle.

6. The electrostatic chuck according to claim 3, wherein
in the widened portion, four of the connecting portions are disposed at positions corresponding to respective vertices of a rectangle.

7. The electrostatic chuck according to claim 4, wherein
in the widened portion, four of the connecting portions are disposed at positions corresponding to respective vertices of a rectangle.
